(19) United States
(12) Patent Application Publication
(10) Pub. No.: US 2025/0251450 A1
(43) Pub. Date: Aug. 7, 2025

(54) ADJUSTABLE TIMING EVENT MONITORING WINDOW

(71) Applicant: MINIMA PROCESSOR OY, Oulu (FI)

(72) Inventors: George KONNAIL, Oulu (FI); Markus HIIENKARI, Oulu (FI); Tuomas HOLLMAN, Oulu (FI); Lauri KOSKINEN, Oulu (FI); Navneet GUPTA, Oulu (FI)

(21) Appl. No.: 18/854,443

(22) PCT Filed: Apr. 5, 2022
(86) PCT No.: PCT/FI2022/050219

§ 371 Date: Oct. 4, 2024

(51) Int. Cl. G01R 31/319; H03K 5/135

(52) U.S. Cl. CPC G01R 31/319; H03K 5/135

(57) ABSTRACT

A microelectronic circuit may comprise at least one timing event detector circuit configured to generate a timing event observation signal as a response to a change in a digital value at an input of an associated register circuit during a timing event monitoring window. The microelectronic circuit may further comprise a control input for adjusting at least a duration of the timing event monitoring window.

### TECHNICAL FIELD

Example embodiments of the present disclosure generally related to the technology of microelectronic circuits that comprise internal monitoring for detecting timing events. Some example embodiments relate to adjusting duration or position of a timing event monitoring (TEM) window.

### BACKGROUND

Processing paths in the microelectronic circuit may be implemented with logic units and register circuits, for example such that a register circuit stores the output value of a preceding logic unit at the rising, falling or both edges of a triggering signal (if the register circuit comprises a flip-flop) or at a high or low level of the triggering signal (if the register circuit comprises a latch). A triggering edge or some other controlling event of the triggering signal (e.g. clock signal) may define an allowable time limit before which a digital value should appear at a data input of the register circuit to become properly stored. The allowable time limit is not necessarily the exact moment of the triggering edge, but defined in some relation to it due to physical effects such as the finite rate at which a voltage level can change. The amount of time required for the data input to be stable before the triggering edge may be referred to as a setup time. On the other hand, in some applications the data input should be stable for a certain time after the triggering edge. The minimum amount of time required for the data input to be stable after the triggering edge may be referred to as the hold time. The logic units may also be referred to as pieces of combinatorial logic.

Monitor circuits may be used to detect timing events. A monitor circuit may comprise a timing event detector circuit. A monitor circuit may comprise a circuit element or functionality added to or associated with a register circuit and configured to produce a timing event observation (TEO) signal in response to detecting a timing event. A timing event may for example comprise a change in the digital value of the data input that took place during the setup time later than said allowable time limit. In addition to the actual monitor circuits, the microelectronic circuit may comprise an OR-tree and/or other structures for collecting, processing, and analysing the TEO signals from the monitor circuits. Monitor circuits can also be used as standalone devices for other applications, such as edge detectors within digital phase-locked loops.

Detection of timing events may trigger compensating actions, for example involving changes in the values of other operating parameters of the circuit, like the clock frequency for example, or temporarily changing the clock waveform.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

Example embodiments of the present disclosure enable optimization of timing event detection by providing a dynamically adjustable TEM window. This and other benefits may be achieved by the features of the independent claims. Further example embodiments are provided in the dependent claims, the description, and the drawings.

According to first aspect, a microelectronic circuit comprises: at least one timing event detector circuit configured to generate a timing event observation signal as a response to a change in a digital value at an input of an associated register circuit during a timing event monitoring window; and a control input for adjusting at least a duration of the timing event monitoring window.

According to an example embodiment of the first aspect, the timing event monitoring window is associated with a respective edge of a clock signal.

According to an example embodiment of the first aspect, the microelectronic circuit further comprises a timing event monitoring window clock generator circuit for generating a timing event monitoring window clock signal indicative of the duration of the timing event monitoring window and a position of the timing event monitoring window with respect to the respective edge of the clock signal.

According to an example embodiment of the first aspect, the timing event monitoring window clock generator circuit is configured to provide the timing event monitoring window clock signal to a single timing event detector circuit, a subset of timing event detector circuits of the microelectronic circuit, or all timing event detector circuits of the microelectronic circuit.

According to an example embodiment of the first aspect, the timing event monitoring window clock generator circuit comprises a tapped delay line for delaying the clock signal.

According to an example embodiment of the first aspect, the timing event monitoring window clock generator circuit is configured to: delay the clock signal to obtain a delayed clock signal; and generate the timing event monitoring window clock signal based on a combination of the clock signal and the delayed clock signal.

According to an example embodiment of the first aspect, the microelectronic circuit is configured to adjust the delay of the delayed clock signal based on the control input in order to adjust the duration of the timing event monitoring window.

According to an example embodiment of the first aspect, the duration of the timing event monitoring window is configured to be adjusted by selecting one of a plurality of outputs of the tapped delay line corresponding to a desired delay.

According to an example embodiment of the first aspect, the combination of the clock signal and the delayed clock signal comprises a NOR operation.

According to an example embodiment of the first aspect, the timing event monitoring window clock generator circuit is configured to delay the clock signal to obtain a delayed clock signal, wherein the delayed clock signal is indicative of the duration of the timing event monitoring window and the position of the timing event monitoring window with respect to the respective edge of the clock signal

According to an example embodiment of the first aspect, the microelectronic circuit is configured to adjust a duty cycle of the delayed clock signal in order to adjust the duration of the timing event monitoring window.

According to an example embodiment of the first aspect, the microelectronic circuit is configured to adjust the delay of the delayed clock signal in order to adjust the position of the timing event monitoring window with respect to the respective edge of the clock signal.

According to an example embodiment of the first aspect, the timing event monitoring window clock generator circuit comprises a time-to-digital converter configured to convert the plurality of outputs of the tapped delay line to a digital value, in response to enabling calibration of the timing event monitoring window clock generator circuit, and the timing event monitoring window clock generator circuit is further configured to: determine a current clock cycle length of the clock signal based on the digital value; and reselect one of the plurality of outputs of the tapped delay line based on the current clock cycle length, in order to substantially maintain the desired delay relative to the current clock cycle length of the clock signal.

According to an example embodiment of the first aspect, the time-to-digital converter comprises a capture register configured to capture the plurality of outputs of the tapped delay line, and wherein the timing event monitoring window clock generator circuit is configured to determine the current clock cycle length of the clock signal based on the captured plurality of outputs of the tapped delay line.

According to an example embodiment of the first aspect, at least part of the timing event monitoring window is before the respective edge of the clock signal.

According to an example embodiment of the first aspect, the timing event monitoring window is before the respective edge of the clock signal and wherein the timing event monitoring window ends at the clock edge.

According to an example embodiment of the first aspect, a second timing event monitoring window is after the edge of the clock signal.

According to an example embodiment of the first aspect, part of the timing event monitoring window is after the edge of the clock signal.

According to an example embodiment of the first aspect, the microelectronic circuit further comprises: a plurality of processing paths comprising logic units and register circuits, wherein the register circuits are configured to temporarily store output values of the logic units in synchronism with the clock signal; a replica path simulating operation of a critical path of the plurality of processing paths, wherein the replica path comprises a one-bit counter with feedback via a delay line matched to the critical path, and wherein the associated register circuit comprises the one-bit counter.

According to a second aspect, a method for operating a microelectronic circuit comprises: generating a timing event observation signal as a response to detecting a change in a digital value at an input of an associated register circuit during a timing event monitoring window; and adjusting at least a duration of the timing event monitoring window.

According to an example embodiment of the second aspect, the timing event monitoring window is associated with a respective edge of a clock signal.

According to an example embodiment of the second aspect, the method further comprises: generating timing event monitoring window clock signal indicative of the duration of the timing event monitoring window and a position of the timing event monitoring window with respect to the respective edge of the clock signal.

According to an example embodiment of the second aspect, the method further comprises: providing the timing event monitoring window clock signal to a single timing event detector circuit, a subset of timing event detector circuits of the microelectronic circuit, or all timing event detector circuits of the microelectronic circuit.

According to an example embodiment of the second aspect, the timing event monitoring window is generated based on a tapped delay line configured to delay the clock signal.

According to an example embodiment of the second aspect, the method further comprises: delaying the clock signal to obtain a delayed clock signal; and generating the timing event monitoring window clock signal based on a combination of the clock signal and the delayed clock signal.

According to an example embodiment of the second aspect, the method further comprises: adjusting the delay of the delayed clock signal based on a control input in order to adjust the duration of the timing event monitoring window.

According to an example embodiment of the second aspect, the duration of the timing event monitoring window is adjusted by selecting one of a plurality of outputs of the tapped delay line corresponding to a desired delay.

According to an example embodiment of the second aspect, the combination of the clock signal and the delayed clock signal comprises a NOR operation.

According to an example embodiment of the second aspect, the method further comprises: delaying the clock signal to obtain a delayed clock signal, wherein the delayed clock signal is indicative of the duration of the timing event monitoring window and the position of the timing event monitoring window with respect to the respective edge of the clock signal.

According to an example embodiment of the second aspect, the method further comprises: adjusting a duty cycle of the delayed clock signal in order to adjust the duration of the timing event monitoring window.

According to an example embodiment of the second aspect, the method further comprises: adjusting the delay of the delayed clock signal in order to adjust the position of the timing event monitoring window with respect to the respective edge of the clock signal.

According to an example embodiment of the second aspect, the timing event monitoring window clock signal is generated based on a time-to-digital converter configured to convert the plurality of outputs of the tapped delay line to a digital value, in response to enabling calibration of the timing event monitoring window clock generator circuit, and the method further comprises: determining a current clock cycle length of the clock signal based on the digital value; and reselecting one of the plurality of outputs of the tapped delay line based on the current clock cycle length, in order to substantially maintain the desired delay relative to the current clock cycle length of the clock signal.

According to an example embodiment of the second aspect, the time-to-digital converter comprises a capture register configured to capture the plurality of outputs of the tapped delay line, and the method further comprises: determining the current clock cycle length of the clock signal based on the plurality of captured outputs of the tapped delay line.

According to an example embodiment of the second aspect, at least part of the timing event monitoring window is before the respective edge of the clock signal.

According to an example embodiment of the second aspect, the timing event monitoring window is before the respective edge of the clock signal and wherein the timing event monitoring window ends at the clock edge.

According to an example embodiment of the second aspect, a second timing event monitoring window is provided after the edge of the clock signal.

According to an example embodiment of the second aspect, part of the timing event monitoring window is after the edge of the clock signal.

According to an example embodiment of the second aspect, the microelectronic circuit comprises a plurality of processing paths comprising logic units and register circuits, wherein the register circuits are configured to temporarily store output values of the logic units in synchronism with the clock signal, and the method further comprises: simulating, by a replica path, operation of a critical path of the plurality of processing paths, wherein the replica path comprises a one-bit counter with feedback via a delay line matched to the critical path, and wherein the associated register circuit comprises the one-bit counter.

Any of the above example embodiments may be combined with one or more other example embodiments. Many of the attendant features will be more readily appreciated as they become better understood by reference to the following detailed description considered in connection with the accompanying drawings.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. In the drawings:

FIG. 1 illustrates an example of a microelectronic circuit with timing event monitoring;

FIG. 2 illustrates an example of a timing event monitoring clock generator circuit configured to generate a timing event monitoring clock signal based on a combination of a clock signal and a delayed clock signal;

FIG. 3 illustrates an example of a timing diagram of signals associated with timing event monitoring clock signal generation based a NOR operation between a clock signal and a delayed clock signal;

FIG. 4 illustrates an example of a timing event monitoring clock generator circuit configured to generate a timing event monitoring clock signal based on a delayed clock signal;

FIG. 5 illustrates an example of a timing diagram of signals associated with timing event monitoring clock signal generation based a delayed clock signal;

FIG. 6 illustrates an example of a timing event window monitoring clock generator circuit with calibration functionality;

FIG. 7 illustrates an example of microelectronic circuit comprising a timing event monitoring circuit associated with a replica path comprising a one-bit counter; and

FIG. 8 illustrates an example of a method for operating a microelectronic circuit.

Like references are used to designate like parts in the accompanying drawings.

### DETAILED DESCRIPTION

In the following, microelectronic circuits and methods for their designing and operating will be described. A microelectronic circuit may comprise a plurality of processing paths comprising logic units and register circuits. A processing path may comprise a sequence of circuit elements through which digital data may pass, so that it gets processed in logic units and temporarily stored in register circuits that are located between consecutive logic units on said processing paths. The register circuits may be configured to temporarily store output values of the logic units in synchronism with a clock signal. The software that the microelectronic circuit executes may define, which processing paths are used at any given time and in which way.

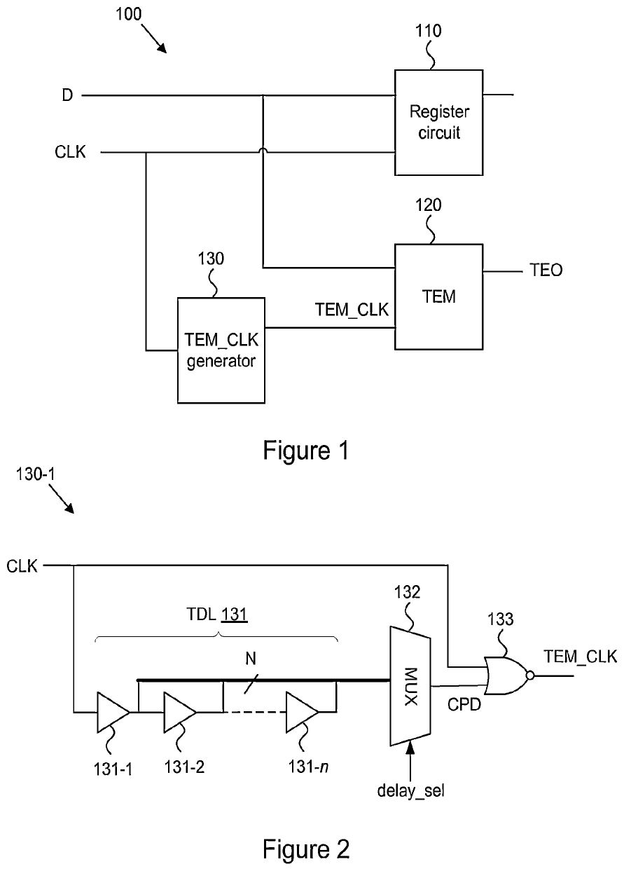

FIG. 1 illustrates an example a microelectronic circuit with timing event monitoring. Microelectronic circuit 100 may comprise a plurality of processing paths, as described above. Microelectronic circuit 100 may comprise a register circuit 110, for example any suitable type of a latch or a flip-flop, optionally in combination with other component(s). Register circuit 110 may belong to one of the processing paths of the microelectronic circuit 100 or a replica path associated with one or more of the processing paths. Register circuit 110 may have a data input for receiving digital values of a data signal (D) and a clock signal input for receiving a clock signal (CLK). The clock signal may be configured as a triggering signal for register circuit 110 to store the digital value (D) currently appearing at the data input, for example at a rising or falling edge of the clock signal. Clock signal CLK may be also referred to as a main clock signal or a data clock signal.

A replica path may be configured to simulate operation of one or more of the processing paths, for example with known input data. If a timing event is detected at the replica path, it may be assumed, with reasonable probability, that timing events occur also at the “actual” processing path(s) under the same operating conditions, e.g., under the influence of the same values of operating parameters like operating voltage, clock frequency, or the like. The operating parameters may be the adjusted to avoid or at least reduce the probability of timing events the processing path(s). For example, the operating voltage may be increased or the clock frequency may be lowered, at least in a respective part of the microelectronic circuit.

Register circuit 110 may be associated with a timing event monitoring (TEM) circuit 120. A data input of TEM circuit 120 may be connected to the data input of register circuit 110. TEM circuit 120 may therefore receive as input a copy of what goes into the data input of register circuit 110. TEM circuit 120 may be configured to generate a timing event observation (TEO) signal, for example as a response to a change in a digital value at the data input (D) of register circuit 110 that took place during a TEM monitoring window associated with a respective edge of the clock signal (CLK), for example later than an allowable time limit before the edge of the clock signal (CLK). For example, the TEO signal may comprise a binary digital signal being normally at a logical low level, but at the moment of detecting a timing event (e.g. a data value change during the TEM window) TEM circuit 120 may raise the TEO signal to a logical high level. The TEO signal may be kept at the logical high level until the end of the clock cycle during which the timing event was observed, or optionally longer.

Each instance of the TEM window may be associated with a respective edge of the clock signal (CLK). Hence, a specific instance of the TEM window enables to monitor timing events associated with the respective clock edge. It is however possible to arrange a TEM window independent of the clock edge to monitor timing events that are not directly associated with an edge of the clock signal. Duration and position of the TEM window may be defined by a TEM window clock signal (TEM_CLK) received as another input at TEM circuit 120. The TEM window may be alternatively called a timing event observation (TEO) window. TEM circuit 120 may be also referred to as a timing event detector circuit.

Microelectronic circuit 100 may further comprise a TEM window clock generator circuit 130, which may be also referred to as a TEM clock generator. TEM window clock generator circuit 130 may be configured to generate the TEM window clock signal (TEM_CLK), for example based on the (main) clock signal (CLK), and to provide the generated TEM_CLK to TEM circuit 120. The TEM window clock signal may be indicative of the duration of the TEM window and the position of the TEM window with respect to the respective clock edge. For example, a logical high or a logical low level of the TEM_CLK may define the position and duration of the TEM window. Examples of TEM window clock generator circuit 130 are described with reference to FIG. 2 and FIG. 4.

TEM window clock generator circuit 130 may provide its output to one or more TEM circuits 120. In one example, TEM_CLK is provided to a single TEM circuit 120. This enables register circuit specific configuration of TEM window. TEM_CLK may be alternatively provided to a group of TEM circuits, for example a subset of TEM circuits of microelectronic circuit 100. The subset may be defined for example by categorizing the TEM circuits based on how likely a timing event will occur in the register circuit they monitor. This likelihood may be estimated for example based on a length of a processing path that precedes the respective TEM circuit without other TEM circuits. Same TEM_CLK signal may be provided to TEM circuits within the same category. This enables to lower the TEM overhead in terms of silicon area, while enabling some extent of TEM window optimization for different parts of microelectronic circuit. It is also possible to provide TEM_CLK to all register circuits of microelectronic circuit 100. This enables very low TEM overhead, since microelectronic circuit 100 may comprise a single TEM window clock signal generator 130.

Microelectronic circuit 100 may comprise a control input for adjusting at least the duration of the TEM window. Optionally, also the position of the TEM window with respect to the respective clock edge may be adjusted. The duration and/or the position of the TEM window may be adjusted dynamically (e.g. during run-time of microelectronic circuit 100), for example based on various operating parameters, e.g. current operating voltage or clock frequency, or a number of timing events detected.

In one example, the control input comprises the TEM window clock signal input of TEM circuit 120. Alternatively, the control input may comprise a control input within TEM window clock generator circuit 130, where the control input may be configured to modify the TEM window clock signal provided to TEM circuit 120, as will be further described for example with reference to FIG. 2. The adjustable TEM window enables to optimize timing at event monitoring microelectronic circuit 100. Monitoring for timing events by TEM circuit 120 consumes power and therefore shortening the duration of the TEM window, whenever possible, enables to save power. Hence, the energy overhead of microelectronic circuit 100 may be reduced.

FIG. 2 illustrates an example of a TEM window clock generator circuit configured to generate a TEM clock signal based on a combination of a clock signal and a delayed clock signal. As noted above, TEM window clock generator circuit, referred to in this example with reference numeral 130-1, may receive the clock signal CLK (main clock) as an input. TEM window clock generator circuit 130-1 may comprise a plurality of delay elements 131-1, 131-2, . . . , 131-n configured to delay the input clock signal. The delay elements may form, or be part of, a tapped delay line (TDL) 131. Outputs of the individual delay elements may be provided, for example by an n-wide bus, to a multiplexer (MUX) 132. Multiplexer 132 may be configured to select one of its inputs (i.e. the clock signal (CLK) corresponding to a desired delay) by control input delay_sel and provide the selected signal (CPD) as output of multiplexer 132. CPD may therefore comprise a delayed version of the clock signal (CLK). The delayed clock signal (CPD) may be combined, for example by any suitable logic operation, with the clock signal CLK to generate the TEM window clock signal (TEM_CLK). Control input delay_sel enables dynamic adjustment of the duration of the TEM window. Microelectronic circuit 100 may therefore adjust the delay of the delayed clock signal (CPD) based on the control input. This may result in adjustment of the duration of the TEM window.

Generating the TEM window clock signal based on the delayed clock signal (CPD), in this example in combination with the (non-delayed) clock signal (CLK), enables the TEM window to be linked to the respective clock edge. Hence, variations in the clock signal, e.g. due to non-idealities of microelectronic circuit 100, may not affect the position of the TEM window with respect to the respective clock edge.

The clock signal (CLK) and the delayed clock signal (CDP) may be combined by any suitable manner, for example by a logic unit (e.g. gate) such as for example a NOR gate 133, as in the example of FIG. 2. It is however appreciated that functionality described herein may be implemented in practice also with different circuit elements, as is common with digital circuits: for example, after having been taught a desired functionality it may be within the capability of the person skilled in the art to present several alternative implementations that differ in e.g. polarity of signals and the resulting need to use circuit elements such as inverters, properly selected logic gates, or the like.

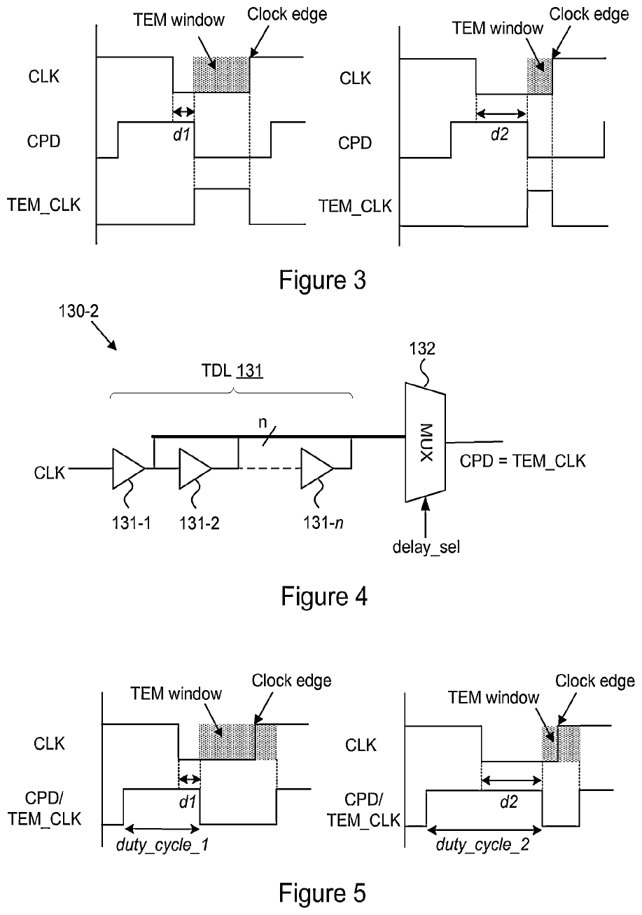

FIG. 3 illustrates an example of a timing diagram of signals associated with timing event monitoring clock signal generation based a NOR operation between a clock signal and a delayed clock signal. This example is provided for the TEM window clock generator circuit 130-1 illustrated in FIG. 2. On the left, the clock signal (CLK) is delayed with delay d1, corresponding to a respective number of delay elements selected by control input delay_sel, to obtain the delayed clock signal (CPD). As defined by NOR gate 133, the TEM_CLK signal goes high when both CLK and CPD are LOW. In this example, the logical high level of TEM_CLK defines the position of the TEM window. In this example, the TEM window is located before the respective clock edge. The TEM window ends at the clock edge. However, to be quite exact, there may be rising and falling times involved also with TEM window, so the actual scope of the TEM window may be generally dependent on CLK and/or CPD, not necessarily beginning and ending at the exact moments of relevant triggering edges thereof.

On the right, the clock signal (CLK) is delayed with delay d2, which is longer than delay d1. The duration of the TEM window is shortened accordingly. It is however noted that position of the end of the TEM window is maintained with respect to the clock edge of CLK (substantially coinciding with the clock edge). Providing (at least part of) the TEM window before the clock edge enables to detect timing events during setup of register circuit 110. Since duration of the TEM window may be adjusted, a dynamically adjustable setup monitoring is provided. Delays d1 and d2 may be selected from a range θ≤d<T_{CLK_LOW}, where T_{CLK_LOW} is the time the clock signal (CLK) takes a particular level defining the TEM window in combination with the delayed clock signal (in this example LOW). TEM window duration may therefore take values from the range 0<d≤T_{CLK_LOW}.

Additionally, a second TEM window may be provided after the respective clock edge. This enables detection of hold violations. The second TEM window may begin substantially at the respective edge of the clock signal (CLK). Hold phase may be more susceptible to random variations (e.g. due to shorter paths, less averaging) than setup phase (e.g. due to longer paths, more averaging). Therefore, in some applications the operating parameters (e.g. a minimum operating voltage, VDD_min) may be derived only based on setup monitoring. Hold cases may persist. It is however of advantage for reliability that setup and hold may be monitored separately.

FIG. 4 illustrates an example of a TEM clock generator circuit configured to generate a TEM window clock signal based on a delayed clock signal. Similar to the example of FIG. 2, TEM window clock generator circuit, denoted by reference numeral 130-2 in this example, may comprise an input for the (main) clock signal (CLK), a tapped delay line 131, and a multiplexer (MUX) 132. The output of the TEM window clock generator 130-2 may be however the delayed clock signal (CPD) directly (TEM_CLK=CPD), rather than a combination of it with the clock signal (CLK). This enables decoupling the end of the TEM window from the respective edge of the clock signal (CLK). The delayed clock signal may be therefore indicative of (e.g. define) both the duration of the TEM window and its position with respect to the respective edge of the clock signal (CLK).

Furthermore, the TEM window clock generator 130-2 may be configured to adjust the duty cycle of the delayed clock signal (CPD), for example by prolonging or shortening the time the delayed clock signal (CDP) stays at the logical high level. Since the TEM window may be defined by a certain level of the delayed clock signal, the duration of the TEM window may be adjusted by adjusting the duty cycle. Furthermore, the position of the TEM window with respect to the respective edge of the clock signal (CLK) may be adjusted by adjusting the delay of CPD, for example by control input delay_sel.

FIG. 5 illustrates an example of a timing diagram of signals associated with TEM clock signal generation based a delayed clock signal. This example is provided for the TEM window clock generator circuit 130-2 illustrated in FIG. 4. On the left, the clock signal (CLK) is delayed with delay d1 to obtain the delayed clock signal (CPD). The CPD, which in this case is the TEM_CLK signal, has a first duty cycle (duty_cycle_1), corresponding to the time CPD is at the logical high level. In this example, the TEM window is defined logical low of level CPD/TEM_CLK. Accordingly, part of the TEM window is before the respective clock edge. Part of the TEM window is after the respective clock edge. The TEM window may continue over the respective clock edge.

On the right, the clock signal (CLK) is delayed with delay d2 to obtain CPD/TEM_CLK. The CPD/TEM_CLK has a second duty cycle (duty_cycle_2), which is longer than the first duty cycle. Since the TEM window is defined by the logical low level of CPD/TEM_CLK, the TEM window on the right is shorter than the TEM window on the left. The duration of the TEM window maybe therefore adjusted by adjusting duty cycle of the delayed clock signal (CPD).

Furthermore, the position of the TEM window with respect to the respective edge of the clock signal (CLK) may be adjusted by the delay of CPD. Hence, it is possible to adjust the also proportion of the TEM window, which is before the clock edge. This enables to dynamically configure behaviour of both setup and hold monitoring. It is advantageous for reliability that both setup and hold may be monitored.

In one example, the delay may be adjusted such that the TEM window is entirely before the clock edge, enabling functionality similar to FIG. 3. Hence, at least part of the TEM window, i.e. the whole TEM window or part of it, may be located before the respective clock edge. Such approach may be referred to as preponing the TEM window (resulting in a preponed TEM window) or advancing the TEM window (resulting in an advanced TEM window). When located entirely before the respective clock edge, the TEM window may end at the respective clock edge.

The TEM window may be decoupled from a time borrowing window. Time borrowing in a microelectronic circuit may refer to allowing a circuit element to temporarily borrow time from a subsequent stage, e.g. to change a digital value later than expected, if the subsequent circuit element(s) on the same processing path can handle it without corrupting the data that is being processed. In other words, a logic unit or other part of processing path that precedes this kind of a register circuit is temporarily allowed to cause a timing event, e.g. a late change of a digital value, if register circuit 110 can handle it without corrupting the data that is being processed. To enable time borrowing, timing events detected during a time borrowing window may be ignored. The occurrence of an instance of time borrowing may be detected as a timing event during the time borrowing window. As indicated above, the time borrowing window may be separate (decoupled) from the time borrowing window.

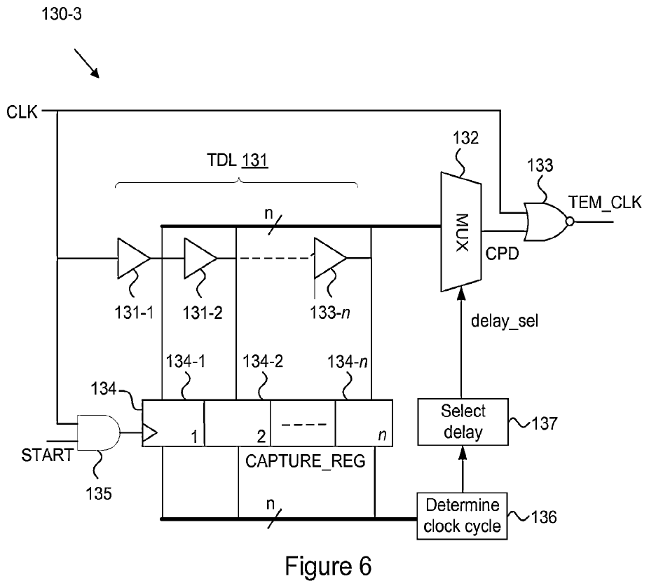

FIG. 6 illustrates an example of a timing event monitoring window clock generator circuit with calibration functionality. Similar to the example of FIG. 2, the TEM window clock generator circuit, denoted by reference numeral 130-3 in this example, may comprise an input for the (main) clock signal (CLK), a tapped delay line 131, a multiplexer (MUX) 132, and a NOR gate 133 configured to combine the clock signal (CLK) and the delayed clock signal (CPD). It is however possible that TEM window clock generator 130-3 is configured similar to the example of FIG. 4, i.e., providing as its output the delayed clock signal directly. The calibration methods described herein maybe therefore applied to TEM clock generator circuits 130-1 and 130-2, as well as other variations thereof.

Calibration may be performed for example because sensitivity of the delay chain (e.g. TDL 131) to PVT (process, voltage, temperature) variations may result in large variation in the monitoring window, both in sense of systematic and random variation due to PVT. Calibration of the delay chain on an ongoing basis enables to keep the TEM window size (duration) accurate even with changes in PVT. In addition, ensuring that small monitoring windows are reliable and accurate enables to reduce overall timing overhead in the system significantly, thereby enabling to apply microelectronic circuit 100 in more timing sensitive, faster applications.

To enable this, TEM window clock generator 130-3 may further comprise a time-to-digital converter (TDC) configured to convert outputs of TDL 131 to a digital value, for example in response to enabling calibration of TEM window clock generator circuit 130-3. An example of such TDC is capture register 134, which may be configured to capture outputs of TDL 131, e.g. at least some outputs of the delay elements (buffers) 131-1, 131-2, . . . , 131-n. Capturing the outputs may be in response to enabling calibration of TEM window clock generator circuit 130-3, for example by providing START signal to enable the clock signal (CLK) to propagate through the AND gate 135 to an enable input of the capture register 134. Clock cycle determination block 136 may be configured to determine a current length of the clock cycle (clock period) of the clock signal (CLK) based on the digital value provided by the TDC, for example the outputs of TDL 131 captured at capture register 134. Values of the capture register may be provided to clock cycle determination block 136 for example via an n-wide bus. Delay selection block 137 may be configured to (re) select one of the TDL outputs based on the current clock cycle length, such that the desired delay relative to current clock cycle length is (substantially) maintained. For example, the TDL output that provides a delay that is closest to the desired delay may be selected. This calibration functionality is further described below.

The output of each delay element 131-1, 131-2, . . . , 131-n may be routed to a respective flip-flop (134-1, 134-2, . . . , 134-n) of the capture register 134, in addition to multiplexer (MUX) 132. Whenever calibration is required by the system, the clock signal (CLK) to the capture register 134 may be released (clock gating removed) for one clock pulse. This way the TDL outputs may be captured into capture register 134 for example at the next positive edge of the clock signal (CLK). At this point, the capture register 134 may contain a pattern of digital values (e.g. zeros and ones). By analysing the captured pattern, clock cycle determination block 136 may determine the clock period of the clock signal (CLK) in terms of number of delay buffers (delay elements of TDL 131). The flip-flop where the digital values changes, e.g. from one to zero, for the first time, may be determined to represent the clock period in terms of number of delay elements. For example, if the value changes from one to zero in at flip-flop number 20, then the clock period may be determined to be equal to 20 buffer delays. This value may be denoted by clock_period.

Based on the clock_period, the tap point to be selected in the delay buffer chain to create a desired delayed version of the clock signal (CLK) may be easily and accurately calculated at delay selection block 137. In case of the previous example, i.e. clock_period=20, if a delay equal to 10% of clock period is desired, delay selection block 137 may select the tap point that is after the second buffer. Or, if a delay equal to 50% of clock period is needed, block 137 may select the tap point to be after the tenth buffer. Calculation of the desired tap point from the values of the capture register 134 may be implemented for example by combinational logic or software. In one example, the output of the TDL 131 as well as the output of the capture register 131 are provided as multi-bit thermometer codes, where b(0), . . . , b(m)=1, b(m+1), . . . , b(n)=0, and where m<n. Parameter m changes relative to the delay. The clock

Furthermore, additional optimizations may be implemented to reduce logic count. For example, not all buffer outputs may be captured into capture register 134. For example, the first few delay buffer outputs may be ignored, for example if the system always has a monitoring window that is larger than half the clock period. Hence, the clock cycle may be determined at block based on outputs of a subset of delay elements of TDL 131. The subset may be determined based on predetermined constraints on the clock cycle or based on previously detected length of the clock cycle. Calibration of the TEM clock generator enables to maintain a desired relative delay with respect to the clock cycle, even when microelectronic circuit 100 is subjected to non-idealities, such for example as PVT changes. In combination with the dynamically adjustable TEM window duration, calibration enables to keep the currently configured TEM window stable.

Calibration of the TEM window clock generator circuit 130 may be done in hardware, e.g. by the TEM window clock generator circuit 130 itself, as described above. Alternatively, calibration of this circuit may be initiated by software, causing the measurement result (i.e. clock period) to be stored in memory. The TEM window configuration (e.g. selection of a particular TDL output) may be then updated by software based on the stored measurement result.

It is however possible to apply the calibration methods described herein to fixed TEM window. Therefore, according to an example embodiment, a microelectronic circuit may comprise: at least one timing event detector circuit configured to generate a timing event observation signal as a response to a change in a digital value at an input of an associated register circuit during a timing event monitoring window associated with a respective edge of a clock signal; and at least one timing event monitoring window clock generator circuit, wherein the timing event monitoring window clock generator circuit comprises a tapped delay line for delaying the clock signal, and wherein the timing event monitoring window clock generator circuit is configured to select one of a plurality of outputs of the tapped delay line corresponding to a desired delay. The timing event monitoring window clock generator circuit may further comprise a time-to-digital converter configured to convert outputs of the tapped delay line to a digital value (e.g. a capture register configured to capture outputs of the tapped delay line), in response to enabling calibration of the timing event monitoring window clock generator circuit. The timing event monitoring window clock generator circuit may be further configured to: determine a current clock cycle length of the clock signal based on the digital value (e.g. the captured outputs of the tapped delay line) and reselect one of the plurality of outputs of the tapped delay line based on the current clock cycle length. This may be done in order to substantially maintain the desired delay. The desired delay may be fixed. Hence, calibration of a fixedly configured TEM window is provided. This enables the keep a fixedly configured TEM window stable regardless PVT variations.

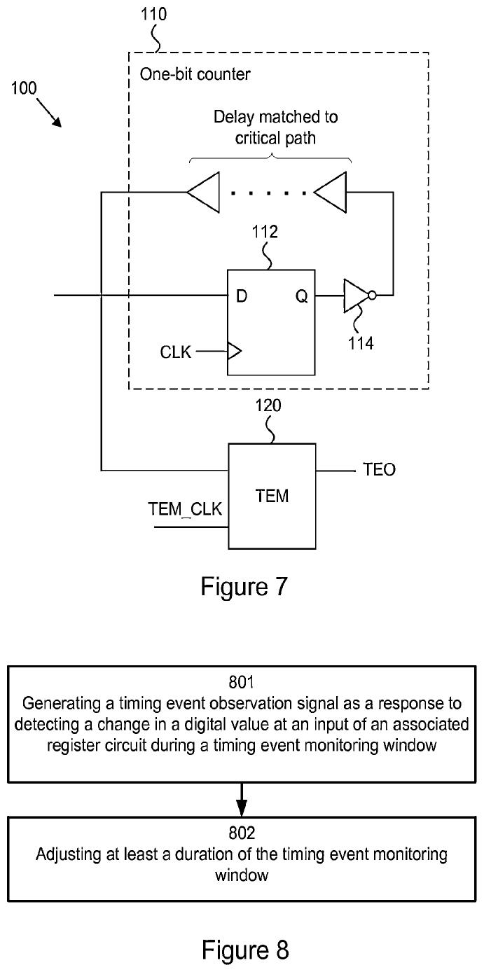

FIG. 7 illustrates an example of a microelectronic circuit comprising a TEM circuit associated with a replica path comprising a one-bit counter. Directly monitoring critical paths may be considered as an accurate way to understand real time variations in circuit speed. This information may be then used for a variety of operations such as adjusting the operating voltage according to the speed of the circuit to ensure that the circuit is always operating at the lowest voltage possible. But, such methods may be less effective in cases where it is difficult to ensure activity on the monitored critical path. Example embodiments of the present disclosure provide good alternatives for these types of paths. For example, TEM window based critical path monitoring solutions may be combined with a single-bit counter based critical path replica, which may be activated for example by enabling the clock signal (CLK) to this circuit. A replica path may be configured to simulate operation of one or more critical paths of the processing paths of microelectronic circuit 100.

Example embodiments of the present disclosure may address the following issues:
Combining monitoring with an easily activated replica path enables to ensure that the system (e.g. microelectronic circuit 100) can activate the replica path and check for the timing margin on the critical path any time without depending on unpredictable activity of the actual critical path.
For a solution based on monitoring critical paths directly, since the activation is random, the overall system solution may take into account the probability of activation. This means that the number of monitors (or monitored paths) may be higher than if the activation was perfect (if the critical paths were always active). Example embodiments of the present disclosure enable increasing the probability of activation to 100%, since the system has control over the activation. This means that the number of monitors may be substantially reduced.
Because it may be indeterminate as to when a critical path will be active, the monitoring solution may be active most of the time to ensure that it does not miss any activity in the critical path. This results in wasted energy while the monitoring is active waiting for activity in the critical path. Example embodiments of the present disclosure enable the system to control activation. This means that the replica and the monitoring can be turned on, for example for only two clock cycles, whenever the system wants to check timing margin. This ensures that the power overhead caused by monitoring will be substantially lower than for a system where the critical paths are directly monitored.

Use of TEM circuits associated with register circuits, the use of replica paths, and other similar arrangements may be generally described so that there are monitoring units associated with respective ones of the processing paths. Each such monitoring unit may be configured to produce a TEO signal as a response to anomalous operation, e.g. a timing event, of the respective processing path. In the case of monitor-equipped register circuits, the monitoring unit may be the monitor circuit. In the case of replica paths, the monitoring unit may comprise the replica path together with the circuit element analysing its output (e.g. TEM circuit 120), and the observation signal may indicate that the output of the replica path was not what it should have been.

In the example of FIG. 7, the TEM window based monitoring approach is combined with a replica path based system, where the replica path is implemented as a single-bit counter (one-bit counter) circuit. As before, microelectronic circuit 100 may comprise TEM circuit 120. However, one-bit counter based replica path may be provided as register circuit 110. The one-bit counter may comprise a flip-flop 112, for example a D-flop, receiving at its data input (D) a digital value, which may be provided also to TEM circuit 120. The flip-flop 112 may further receive the clock signal (CLK). The one-bit counter may further comprise an inverter 114 to provide inverted feedback to its data input (D). The feedback path may comprise a delay chain (delay line), comprising one or a plurality of delay elements, such that the delay of the delay chain is matched to the delay of the critical path.

The one-bit counter may be activated by enabling the clock signal to the one-bit counter. The clock signal may be enabled for two clock cycles, e.g., one clock cycle for launch and one clock cycle for capture. Matching the delay of the feedback path of the one-bit counter to the critical path to be monitored solves the problem of the unpredictability of activation, because both the critical path replica and the monitor can be activated for one clock cycle at the same time.

Alternative to the one-bit counter of FIG. 7, also other type of replica paths may be used. For example, the TEM clock generator circuits 130-1 or 130-2 may be used to implement a replica path. In that those circuits case, may be configured with characteristics similar to the one-bit counter of FIG. 7. For example, the delay of those circuits may be matched to the delay of the critical path(s). Following advantages are provided:
Because the system can directly activate the critical path replica any time, the activity probability is 100% (perfect activation). This means that the number of monitors (or monitored paths) needed is substantially less than for a system where activation is unpredictable.
Because the system can directly activate the critical path replica any time, there it is not needed to enable the monitoring all the time. Monitoring can be therefore enabled for example for two clock cycles at the same time that the replica path is activated. This ensures that the energy consumed by monitoring is substantially lower.
The one-bit counter based critical path replica requires no settling time. This means there is no wasted energy when waiting for the circuit to settle. Furthermore, window based monitoring can be completed in two clock cycles. This means that there is minimum delay in measurement and hence no extra timing margin is required to compensate for measurement or settling delays.
The performance (or timing margin) of the one-bit counter based replica path can be easily measured using a window based monitoring solution.

FIG. 8 illustrates an example of a method for operating a microelectronic circuit.

At 801, the method may comprise generating a timing event observation signal as a response to detecting a change in a digital value at an input of an associated register circuit during a timing event monitoring window.

At 802, the method may comprise adjusting at least a duration of the monitoring window.

Further features of the method directly result from functionalities of microelectronic circuit 100, as described throughout the specification and in the appended claims, and are therefore not repeated here. Different variations of the methods may be also applied, as described in connection with the various example embodiments.

An apparatus, such as for example microelectronic circuit 100, a component of a microelectronic circuit 100, or an apparatus (e.g. computing device) comprising microelectronic circuit 100 may be configured to perform or cause performance of any aspect of the method(s) described herein. Further, an apparatus may comprise means for performing any aspect of the method(s) described herein. According to an example embodiment, the means comprises circuitry described herein.

It is obvious to a person skilled in the art that with the advancement of technology, the example embodiments may be implemented in various ways. For example, logic functionalities may be replaced with structurally different but operationally equivalent functionalities, by taking into account the possible inversions and logic conversions that are needed. The present disclosure is therefore not limited to the examples described above, instead they may vary within the scope of the claims.

1. A microelectronic circuit, comprising:
at least one timing event detector circuit configured to generate a timing event observation signal as a response to a change in a digital value at an input of an associated register circuit during a timing event monitoring window; and
a control input for adjusting at least a duration of the timing event monitoring window.

2. The microelectronic circuit according to claim 1, wherein the timing event monitoring window is associated with a respective edge of a clock signal.

3. The microelectronic circuit according to claim 2, further comprising a timing event monitoring window clock generator circuit for generating a timing event monitoring window clock signal indicative of the duration of the timing event monitoring window and a position of the timing event monitoring window with respect to the respective edge of the clock signal.

4. The microelectronic circuit according to claim 3, wherein the timing event monitoring window clock generator circuit is configured to provide the timing event monitoring window clock signal to a single timing event detector circuit, a subset of timing event detector circuits of the microelectronic circuit, or all timing event detector circuits of the microelectronic circuit.

5. The microelectronic circuit according to claim 3, wherein the timing event monitoring window clock generator circuit comprises a tapped delay line for delaying the clock signal.

6. The microelectronic circuit according to claim 3, wherein the timing event monitoring window clock generator circuit is configured to:
delay the clock signal to obtain a delayed clock signal; and
generate the timing event monitoring window clock signal based on a combination of the clock signal and the delayed clock signal.

7. The microelectronic circuit according to claim 6, wherein the microelectronic circuit is configured to adjust the delay of the delayed clock signal based on the control input in order to adjust the duration of the timing event monitoring window.

8. The microelectronic circuit according to claim 5, wherein the duration of the timing event monitoring window is configured to be adjusted by selecting one of a plurality of outputs of the tapped delay line corresponding to a desired delay.

9. The microelectronic circuit according to claim 5, wherein the combination of the clock signal and the delayed clock signal comprises a NOR operation.

10. The microelectronic circuit according to claim 3, wherein the timing event monitoring window clock generator circuit is configured to delay the clock signal to obtain a delayed clock signal, wherein the delayed clock signal is indicative of the duration of the timing event monitoring window and the position of the timing event monitoring window with respect to the respective edge of the clock signal.

11. The microelectronic circuit according to claim 10, wherein the microelectronic circuit is configured to adjust a duty cycle of the delayed clock signal in order to adjust the duration of the timing event monitoring window.

12. The microelectronic circuit according to claim 10, wherein the microelectronic circuit is configured to adjust the delay of the delayed clock signal in order to adjust the position of the timing event monitoring window with respect to the respective edge of the clock signal.

13. The microelectronic circuit according to claim 5, wherein the timing event monitoring window clock generator circuit comprises a time-to-digital converter configured to convert the plurality of outputs of the tapped delay line to a digital value, in response to enabling calibration of the timing event monitoring window clock generator circuit, wherein the timing event monitoring window clock generator circuit is further configured to:
determine a current clock cycle length of the clock signal based on the digital value; and
reselect one of the plurality of outputs of the tapped delay line based on the current clock cycle length, in order to substantially maintain the desired delay relative to the current clock cycle length of the clock signal.

14. The microelectronic circuit according to claim 13, wherein the time-to-digital converter comprises a capture register configured to capture the plurality of outputs of the tapped delay line, and wherein the timing event monitoring window clock generator circuit is configured to determine the current clock cycle length of the clock signal based on the captured plurality of outputs of the tapped delay line.

15. The microelectronic circuit according to claim 2, wherein at least part of the timing event monitoring window is before the respective edge of the clock signal.

16. The microelectronic circuit according to claim 15, wherein the timing event monitoring window is before the respective edge of the clock signal and wherein the timing event monitoring window ends at the respective edge of the clock signal.

17. The microelectronic circuit according to claim 16, wherein a second timing event monitoring window is after the respective edge of the clock signal.

18. The microelectronic circuit according to claim 15, wherein part of the timing event monitoring window is after the respective edge of the clock signal.

19. The microelectronic circuit according to claim 1, further comprising:
a plurality of processing paths comprising logic units and register circuits, wherein the register circuits are configured to temporarily store output values of the logic units in synchronism with the clock signal;
a replica path simulating operation of a critical path of the plurality of processing paths, wherein the replica path comprises a one-bit counter with feedback via a delay line matched to the critical path, and wherein the associated register circuit comprises the one-bit counter.

20. A method for operating a microelectronic circuit, the method comprising:
generating a timing event observation signal as a response to detecting a change in a digital value at an input of an associated register circuit during a timing event monitoring window; and
adjusting at least a duration of the timing event monitoring window.

21.-38. (canceled)
